(19) United States
(12) Patent Application Publication
(10) Pub. No.: US 2010/0026337 A1
(43) Pub. Date: Feb. 4, 2010

(54) Interdependent Microchip Functionality for Defeating Exploitation Attempts

(75) Inventors: Gerald K. Bartley, Rochester, MN (US); Darryl J. Becker, Rochester, MN (US); Paul E. Dahlen, Rochester, MN (US); Philip R. Germann, Oronoco, MN (US); Andrew B. Maki, Rochester, MN (US); Mark O. Maxson, Mantorville, MN (US); John E. Sheets, II, Zumbrota, MN (US)

Correspondence Address: IBM-Rochester c/o Toler Law Group, 8500 Bluffstone Cove, Suite A201, Austin, TX, 78759, US

(73) Assignee: INTERNATIONAL BUSINESS MACHINES CORPORATION, Armonk, NY (US)

(21) Appl. No.: 12/181,376

(22) Filed: Jul. 29, 2008

(51) Int. Cl. H03K 19/00

(52) U.S. Cl. 326/8

(57) ABSTRACT

An integrated circuit assembly comprising a microchip that shares an interdependent function with a second, stacked microchip. Alternation of the physical arrangement or functionality of the microchips may initiate a defense action intended to protect security sensitive circuitry associated with one of the microchips. The microchips may communicate using through-silicon vias or other interconnects.

### RELATED APPLICATIONS

The present application relates to co-pending U.S. patent applications entitled “Capacitance-Based Microchip Exploitation Detection” (Docket No. ROC920080089US1), “Signal Quality Monitoring to Defeat Microchip Exploitation” (Docket No. ROC920080090US1), “False Connection for Defeating Microchip Exploitation” (Docket No. ROC920080092US1), “Capacitance Structures for Defeating Microchip Tampering” (Docket No. ROC920080094US1), “Resistance Sensing for Defeating Microchip Exploitation” (Docket No. ROC920080115US 1), “Continuity Check Monitoring for Microchip Exploitation Detection” (Docket No. ROC920080091US1), and “Doped Implant Monitoring for Microchip Tamper Detection” (Docket No. ROC920080139US1), all of which are filed concurrently herewith and which are incorporated by reference in their entireties.

### FIELD OF THE INVENTION

The present invention relates generally to microchip technologies, and more particularly, to protecting the circuitry and content of microchips.

### BACKGROUND OF THE INVENTION

Protecting microchip technology deployed in the field is an enormous concern in both military and commercial sectors. Microchips and related devices are routinely acquired by motivated competitors and governments seeking to reverse engineer or otherwise learn the functionality of the technology. Such information is used to make a technological leap in their own devices, or may be used to exploit a perceived weakness in the examined equipment. Sophisticated government and commercial entities thus possess ample strategic and economic motivation to reverse engineer microchip components.

A microchip, or integrated circuit, is a unit of packaged computer circuitry that is manufactured from a material, such as silicon, at a very small scale. Microchips are made for program logic (logic or microprocessors) and for computer memory (Random Access Memory or other memory microchips). Microchips are also made that include both logic and memory, and for special purposes, such as signal, graphics and other processing applications.

An advanced method of reverse engineering select microchip components uses high energy photons, electrons or ions. Focused ion beam processes excite active portions of a microchip to observe how other portions are affected. When used to reverse engineer, these processes are typically done while the microchip is in a powered-on state in order to observe the functionality of the microchip.

Microchip designers in the aerospace, defense and commercial industries routinely implement software and other logic-related techniques to confuse and thwart attempts to probe the active side of the component. For example, safeguard measures integrated within microchips hinder reverse engineering techniques. Microchip designers capitalize on the powered on status required by a reverse engineering process to incorporate a self-destruct or obstructing mechanism into the microchip. The mechanism is triggered by the detection of tampering. When tampering is detected, the power in the circuit is diverted to microchip annihilation or another predetermined measure.

Microchip designers occasionally impede the reverse engineering processes by additionally plating the back of the bulk silicon with a metal layer. While intact, this layer obstructs both the insertion of ions and electrons, and the observation of photons.

While these safeguards provide some protection, motivated exploiters have developed ingenious ways of analyzing the microchip without triggering the safeguard mechanisms. Despite the precautions, the backside of the microchip remains vulnerable to inspection by photons, focused ion beam, or even simple infrared observation. Sophisticated exploitation techniques overcome conventional obstacles by removing the bulk silicon and metallized back layer. For instance, reverse engineering processes may grind away the metallized portion towards implementing a successful focused ion beam operation. In this manner, microchip information may be exploited in a manner that does not initialize a self-destruct feature.

Consequently what is needed is an improved manner of detecting tampering of a microchip.

### SUMMARY OF THE INVENTION

The present invention provides an improved method, apparatus and program product for protecting security sensitive circuitry of a microchip from undesired analysis by providing, in part, a first microchip including logic circuitry, and a second microchip including dependent logic circuitry that depends upon the logic circuitry of the first microchip to perform a function. Circuitry in electronic communication with at least one of the first and second microchips may be configured to initiate an action for obstructing analysis of security sensitive circuitry in response to a detected interruption in the performance of the function. The circuitry may be further configured to detect the interruption in the performance of the function.

An embodiment that is consistent with the invention may comprise circuitry that includes a performance screen ring oscillator. In another or the same embodiment, the first and second microchips may be positioned in a stacked arrangement. The detected interruption may be caused by an alteration of at least one of the logic circuitry and the dependent logic circuitry.

According to an aspect of the invention, the security sensitive circuitry may reside in either or both of the first and second microchips. The logic and dependent logic circuitry comprise interlocking signaling functions. Additionally or alternatively, the logic and dependent logic circuitry may share functional logic processes. In another or the same embodiment, the logic and dependent logic circuitry may share pervasive logic processes. The logic and dependent logic circuitry may share timing-related logic processes.

According to another aspect of the invention, a connection may connect at least one of the first and second microchips to the circuitry. An exemplary such connection may comprise a through-silicon via. Embodiments consistent with the invention may include program code executed by the circuitry and configured to initiate the action for obstructing analysis of the security sensitive circuitry in response to the detected interruption in the performance of the function, and a computer/machine readable medium bearing the program code. The defensive action may include one or more of a shutdown, a spoofing, or a self-destruct operation.

Another embodiment of the invention may include interdependent circuitry allocated between a plurality of microchips. Alteration of the interdependent circuitry may cause a deviation from an expected performance of the independent circuitry. Circuitry in electronic communication with at least one of the plurality of microchips may be configured to initiate an action for obstructing analysis of security sensitive circuitry in response to the detected deviation from the expected performance.

According to another aspect of the invention, a method may protect security sensitive circuitry of a microchip from undesired analysis by sensing a deviation from an expected performance by a function executed by interdependent circuitry distributed between a plurality of microchips, and initiating a defensive action configured to obstruct analysis of the security sensitive circuitry in response to sensing the deviation from the expected performance. The plurality of microchips may be arranged in a stacked configuration. Aspects of the invention may use a performance screen ring oscillator to sense the deviation from the expected performance. The expected performance may relate to a performance of a function. The defensive action may include at least one of a shutdown, a spoofing, or a self-destruct operation.

These and other advantages and features that characterize the invention are set forth in the claims annexed hereto and forming a further part hereof. However, for a better understanding of the invention, and of the advantages and objectives attained through its use, reference should be made to the Drawings and to the accompanying descriptive matter in which there are described exemplary embodiments of the invention.

### BRIEF DESCRIPTION OF THE DRAWINGS

FIG. 1 shows a perspective view of integrated circuit assembly that includes a microchip sharing an interdependent function with a second microchip and that is configured to detect a tampering operation in accordance with the underlying principles of the present invention.

FIG. 2 shows a block diagram of an integrated circuit assembly that includes interdependent microchips, such as that shown in FIG. 1.

FIG. 3 shows a flowchart having steps executable by the integrated circuit assembly of FIG. 2 for detecting a tampering attempt affecting interdependent microchips, and for initiating a defensive action in response to the tampering.

### DETAILED DESCRIPTION

Embodiments consistent with the underlying principles of the present invention include an integrated circuit assembly comprising a microchip that shares an interdependent function with a second, stacked microchip. Alternation of the physical arrangement or functionality of the microchips may initiate a defense action intended to protect security sensitive circuitry associated with one of the microchips.

Aspects of the invention capitalize on microchip stacking techniques and through-silicon via technology to hide and/or spread out security sensitive circuitry. A microchip positioned on top of another may shield and camouflage another microchip, positioned below and having exploitable circuitry. Interlocking signaling between the stacked microchips may be sensed to determine if a top, shielding microchip die is removed. Timing critical paths may be interspersed and interlocked between the top, parasitic microchip and the bottom microchip in such a manner that replication of the timing becomes very difficult once the microchips are separated.

The top microchip may serve as a shield for the security sensitive circuitry residing in the second microchip. Interconnections between the two microchips may be functional (e.g., useful circuitry that nonetheless may not be security sensitive) and/or false and misleading in nature. Signal timings may be tuned to be so sensitive as to make it extremely challenging to make the function run should the microchips become separated. The absence of the top microchip, the violation of timings and/or a change in loading on a signal may trigger a self-destruct or other defensive mechanism.

Another or the same embodiment may use a performance screen ring oscillator, which generally includes a string of inverters formed in a loop. More particularly, a performance screen ring oscillator may be stitched multiple times in alternating fashion between the two stacked microchips. If the performance screen ring oscillator quits running, the function of the device may cease. Continuity testing, e.g., loops of connections between the two microchips, may also be used to determine if the parasitic microchip has been removed or altered.

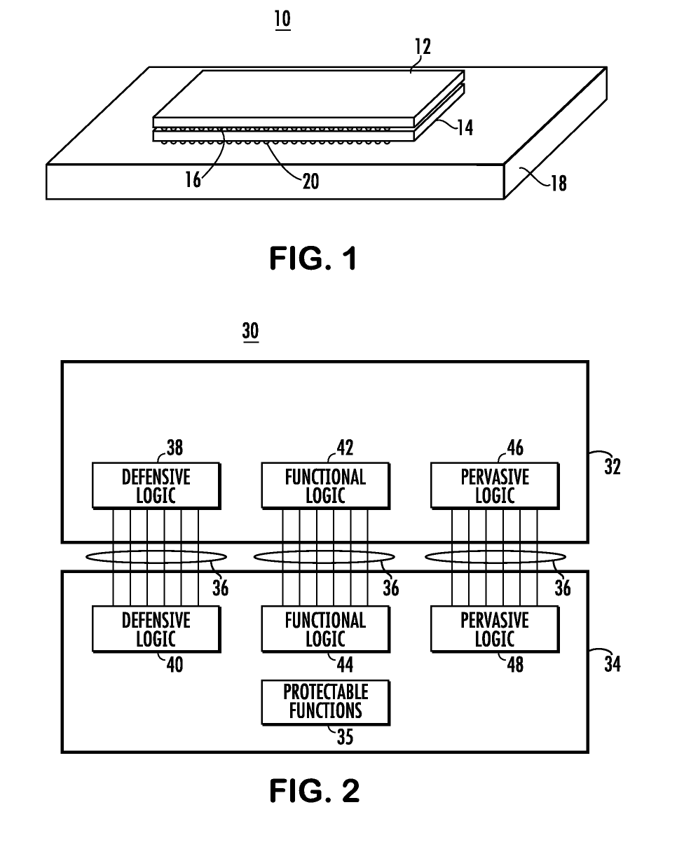

FIG. 1 shows a perspective view of an integrated circuit assembly 10 that includes a microchip 12 sharing an interdependent function with a second microchip 14. Alternation of the physical arrangement or functionality of the microchips 12, 14 may initiate a defensive action. The microchips 12, 14 may communicate using vias 16 or other interconnects. A through-silicon via is a type of via that comprises a vertical electrical connection passing through a silicon wafer or die for the purpose of creating three-dimensional packages and circuits. Embodiments may alternatively or additionally use die bump interconnects 20. Such interconnects 20 may connect a microchip 14 to a microchip carrier 18.

The microchip 12 may function to shield, camouflage and/or otherwise protect the microchip 14 upon which it is stacked. That is, attempts to access the security sensitive circuitry of the microchip 14 that involve altering the state of the microchip 12 may initiate the defensive action. Exemplary defensive actions may include shutdown, spoofing and self-destruct actions, among others.

In one sense, the integrated circuit assembly 10 of FIG. 1 comprises a stacked microchip assembly. The close proximity of the microchips 12, 14 to one another may enable designers to omit input/output (I/O) logic without significant regard to protocol layers and/or the physical layer (PHY) of the Open Systems Interconnection Basic Reference Model (OSI Model). Should the microchips 12, 14 become separated, the defensive action may be triggered.

FIG. 2 shows a block diagram of an integrated circuit assembly 30 that includes interdependent microchips 32, 34. The microchips 32, 34 may have codependent functionality. As shown in FIG. 2, the microchips 32, 34 may be connected using vias 36. Of note, should one of the vias 36 become disconnected, the associated and connected functions may cease to operate as expected or at all.

The microchip 34 may include security sensitive functions 35, or logic circuitry. Security sensitive functions 35 may comprise firmware, software, and/or hardware of potentially compromising value. Defensive logic 38, 40 may initiate a defensive action on the security sensitive function 35 in the event of detected tampering of the paired microchips 32, 34.

The microchips 32, 34 may additionally share functional logic 42, 44. Examples of functional logic may be accomplished by the microchips 32, 34 in concert to accomplish any task, to include initialization processes, writing/reading functions, or any task for which the processes and associated circuitry may be divided among the microchips 32, 34. Functional logic may, but does not typically include I/O logic or protocol considerations. Functional logic may further comprise pervasive logic 46, 48, which may be responsible for or reliant upon specific timing mechanisms or load characteristic requirements. Pervasive logic 46, 48 may include monitoring and clocking functions, and be shared between the interdependent microchips 32, 34.

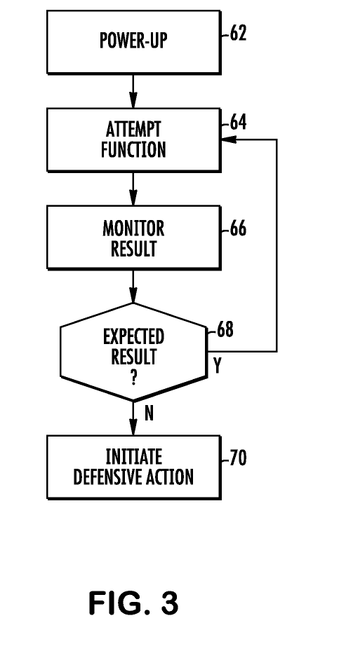

FIG. 3 is a flowchart 60 showing steps executable by the integrated circuit assembly 30 of FIG. 2 for detecting a tampering attempt affecting interdependent microchips 32, 34 and for initiating a defensive action in response to the tampering. Turning more particularly to the steps of the flowchart 60, the integrated circuit assembly 30 may power-up at block 62. While many embodiments may sense any and all interruptions or alternations of the physical structure and/or logic associated with either interdependent microchip 32, 34, other embodiments may selectively monitor specific aspects of the paired microchips 32, 34. As such, the system assembly 30 may determine automatically which functions should be monitored at power-up at block 62.

At block 64 of FIG. 3, the integrated circuit assembly 30 may attempt to accomplish a function. As discussed herein, the function may be interdependent as between the microchips 32, 34. As such, the attempted function may include physical connections, as well as instructions executed by circuitry.

The integrated circuit assembly 30 may monitor at block 66 the result of the attempted function. An exemplary monitored result may include a signal indicative of the failure of the function. Another result may include a measured value, such as signal strength associated with the function. Sensing circuitry may include any known process and hardware for detecting the tampering of a component of the integrated circuit assembly 30.

The result may be registered or compared at block 68 to an inspected result or performance. Should the result conform with an acceptable or expected performance and otherwise not indicate an assembly alteration, the assembly 30 may continue to function and monitor at blocks 64 and 66.

Alternatively, where a tampering event is detected at block 68, the integrated circuit assembly 30 may initiate at block 70 a defensive action. Examples of defensive actions include spoofing, shutdown and self-destruct processes.

While the invention has and hereinafter will be described in the context of integrated circuit assemblies, those skilled in the art will appreciate that the various embodiments of the invention are capable of being distributed as a program product in a variety of forms, and that the invention applies equally regardless of the particular type of machine/computer readable, signal bearing media used to actually carry out the distribution. For instance, a separate processor incorporated within or otherwise in communication with an integrated circuit assembly may access memory to execute program code functions to identify tampering in a software manner that is consistent with the underlying principles of the present invention. Examples of signal bearing, machine/computer readable media include, but are not limited to tangible, recordable type media such as volatile and non-volatile memory devices, floppy and other removable disks, hard disk drives, magnetic tape, optical disks (e.g., CD-ROMs, DVDs, etc.), among others, and transmission type media such as digital and analog communication links.

In general, the routines executed to implement the embodiments of the invention, whether implemented in hardware, as part of an integrated circuit assembly, or as a specific application, component, program, engine, process, programmatic tool, object, module or sequence of instructions, or even a subset thereof, may be referred to herein as an “algorithm,” “function,” “program code,” or simply “program.” Program code typically comprises one or more instructions that are resident at various times in various memory and storage devices in a computing system. When read and executed by one or more processors, the program code performs the steps necessary to execute steps or elements embodying the various aspects of the invention. One of skill in the art should appreciate that embodiments consistent with the principles of the present invention may nonetheless use program code resident at only one, or any number of locations.

Those skilled in the art will further recognize that the exemplary environments illustrated in FIGS. 1-4 are not intended to limit the present invention. For instance, while flip chip mounting processes are used in many of the embodiments above for exemplary purposes, embodiments of the invention may have equal applicability to microchip assemblies associated with virtually any other mounting technique. Indeed, those skilled in the art will recognize that other alternative hardware and/or software environments may be used without departing from the scope of the invention.

Moreover, while the present invention has been illustrated by a description of various embodiments and while these embodiments have been described in considerable detail, it is not the intention of the Applicants to restrict, or in any way limit the scope of the appended claims to such detail. The invention in its broader aspects is therefore not limited to the specific details, representative apparatus and method, and illustrative example shown and described. Accordingly, departures may be made from such details without departing from the spirit or scope of Applicants' general inventive concept.

What is claimed is:

1. An apparatus comprising:
a first microchip including logic circuitry;
a second microchip including dependent logic circuitry that depends upon the logic circuitry of the first microchip to perform a function; and
circuitry in electronic communication with at least one of the first and second microchips and configured to initiate an action for obstructing analysis of the security sensitive circuitry in response to a detected interruption in the performance of the function.

2. The apparatus of claim 1, wherein the circuitry is further configured to detect the interruption in the performance of the function.

3. The apparatus of claim 1, wherein the circuitry includes a performance screen ring oscillator.

4. The apparatus of claim 1, wherein the first and second microchips are positioned in a stacked arrangement.

5. The apparatus of claim 1, wherein the detected interruption is caused by an alteration of at least one of the logic circuitry and the dependent logic circuitry.

6. The apparatus of claim 1, wherein the security sensitive circuitry resides in at least one of the first and second microchips.

7. The apparatus of claim 1, wherein the logic and dependent logic circuitry comprise interlocking signaling functions.

8. The apparatus of claim 1, wherein the logic and dependent logic circuitry share functional logic processes.

9. The apparatus of claim 1, wherein the logic and dependent logic circuitry share pervasive logic processes.

10. The apparatus of claim 1, wherein the logic and dependent logic circuitry share timing-related logic processes.

11. The apparatus of claim 1 further comprising a connection connecting at least one of the first and second microchips to the circuitry.

12. The apparatus of claim 11, wherein the connection comprises a through-silicon via.

13. The apparatus of claim 1, further comprising program code executed by the circuitry and configured to initiate the action for obstructing analysis of the security sensitive circuitry in response to the detected interruption in the performance of the function; and a computer readable medium bearing the program code.

14. The apparatus of claim 1, wherein the defensive action includes an operation selected from a group consisting of at least one of: a shutdown, a spoofing and a self-destruct operation.

15. An apparatus comprising:
interdependent circuitry allocated between a plurality of microchips, wherein the alteration of the interdependent circuitry causes a deviation from an expected performance of the interdependent circuitry; and
circuitry in electronic communication with at least one of the plurality of microchips and configured to initiate an action for obstructing analysis of the security sensitive circuitry in response to the detected deviation from the expected performance.

16. A method of protecting security sensitive circuitry of a microchip from undesired analysis, the method comprising:
sensing a deviation from an expected performance by a function executed by interdependent circuitry distributed between a plurality of microchips; and
initiating a defensive action configured to obstruct analysis of the security sensitive circuitry in response to sensing the deviation from the expected performance.

17. The method of claim 16, further comprising arranging the plurality of microchips in a stacked configuration.

18. The method of claim 16, wherein sensing the deviation further comprises using a performance screen ring oscillator.

19. The method of claim 16, wherein the expected performance relates to a performance of a function.

20. The method of claim 16, wherein initiating the defensive action further comprises initiating an operation selected from a group consisting of at least one of: a shutdown, a spoofing and a self-destruct operation.
